(19) United States
(12) Patent Application Publication
(10) Pub. No.: US 2008/0231478 A1
(43) Pub. Date: Sep. 25, 2008

(54) Solid Oxide Fuel Cell With Sealed Structure

(76) Inventors: Mohamed Benali Khoudja, Antony (FR); Moustapha Hafez, Paris (FR)

Correspondence Address: ANDERSON, KILL & OLICK, P.C., 1251 AVENUE OF THE AMERICAS, NEW YORK,, NY, 10020-1182, US

(21) Appl. No.: 10/593,512

(22) PCT Filed: Mar. 22, 2005
(86) PCT No.: PCT/JP05/50182

§ 371 Date: Sep. 19, 2006

(30) Foreign Application Priority Data
Mar. 24, 2004 (JP) 04 50581

(51) Int. Cl. H03K 17/94

(52) U.S. Cl. 341/35

(57) ABSTRACT

This tactile interface includes a layer (5) of pins (4) that the user can touch with the fleshy part of one of his fingers. The pins (4) are free to rotate and their spacing can be adjusted using an appropriate system. They can be provided with edges to assist in simulating other textures.

This invention relates to a tactile interface.

For example, such interfaces are used in simulation or virtual environment techniques, for example used to make the operator feel specific tactile sensations. There are various types of interfaces. This description applies to interfaces giving the most realistic possible impression of the contact and exploration of a surface, and particularly a textured surface or a surface with other relief.

A known interface comprises a network of actuators arranged in a matrix and in which the tips face upwards so as to touch the fleshy part of an operator's finger placed on the interface, as described in the article “Electromagnetically Driven High-Density Tactile Interface Based on a Multi-Layer Approach”, by Benali-Khoudja et al, MHS, pp.147-152, Nagoya (Japan) 2003. The actuators give the illusion of contact with the surface and its relief due to the different forces or movements applied on the flesh of the finger. A cyclic movement of each actuator can displace the pattern of relief produced by the matrix and simulate movement of the finger on the virtual surface. The impression of contact is well restored, but this interface is somewhat complicated due to the large number of actuators. Furthermore, it may be difficult to adjust forces or movements to correct values.

There is also a portable interface in which a single roll is placed under the flesh of the finger and is made to rotate about an axis parallel to the finger, so as to impose lateral forces on the skin (“Exos slip display research and development” by Chen and Marcus, DSC-vol.55-1, Dynamic Systems and Control, volume 1, ASME 1994). This other interface is suitable for simulating the impression produced by moving the finger over a surface, but not for creating the feel of relief or a texture.

The subject of the invention is an interface capable of giving almost the same variety of impressions as the first interface mentioned, but with a simpler composition and easier adjustment.

In its general form, this new interface comprises a row of rotating pins, preferably parallel, mounted on corresponding supports and forming a layer on which a user places a finger, and a support spacing adjustment mechanism.

The layer of pins does give a variety of impressions comparable to actuators arranged in a two-dimensional matrix. The interface control system has two possible means of adjustment. The variable spacing of the supports can simulate various surface textures. Rotation of the pins at different speeds contributes to the same effects, while also giving the impression of displacement on the simulated surface.

The pins can be provided with edges: the variety of simulated textures, and particularly of the frequency of relief, is enriched.

One particularly advantageous embodiment of the interface is obtained if the supports slide on guide ways and the spacing adjustment mechanism comprises connections in a parallelogram arrangement between the supports and a means for moving one of the supports.

Another advantageous composition is characterised in that it includes a frame on which the pin supports are mounted free to move, at least one pin drive motor mounted fixed onto the frame, and transmissions between the motor and the various pins and comprising first universal joints adjacent to the motor and second universal joints adjacent to the pins, and telescopic transmission bars between the first universal joints and the second universal joints.

Finally, the interface can include a temperature variation module placed under the layer of pins so as to make the user feel an impression of heat.

We will now describe a preferred embodiment of the invention:

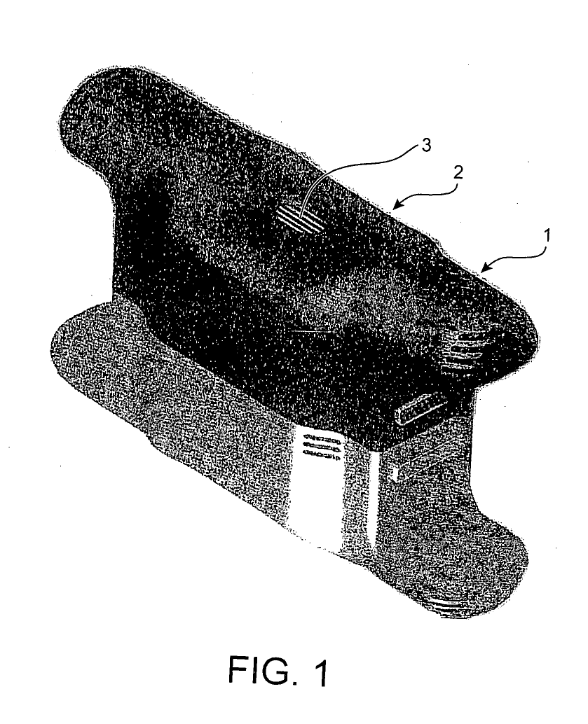

FIG. 1 shows an external view of the tactile interface according to the invention,

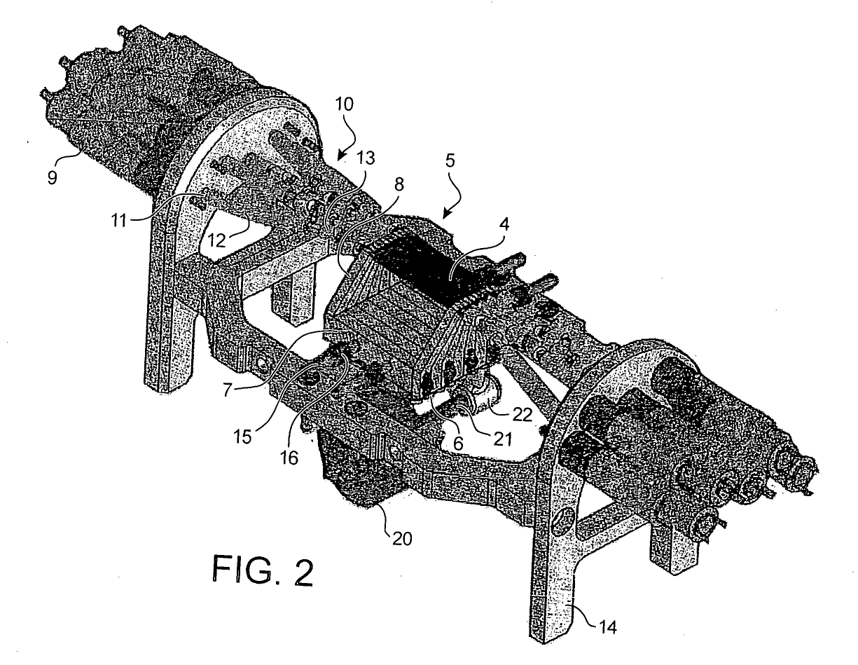

FIG. 2 shows the interface, with the external casing removed,

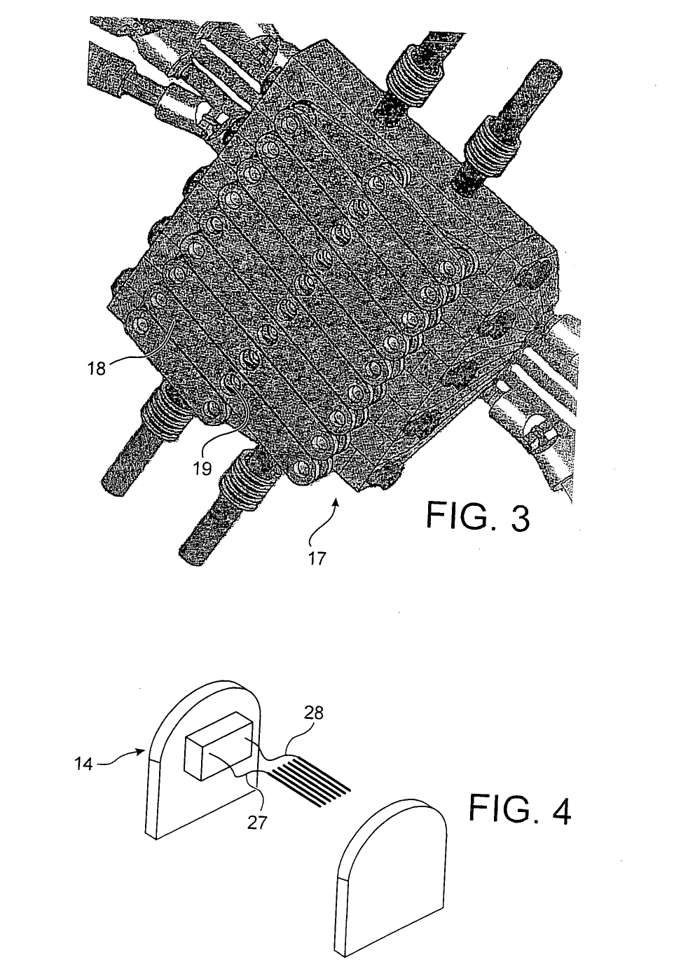

FIG. 3 shows the pin spacing mechanism, and

FIG. 4 illustrates a particular aspect of the invention.

One embodiment as seen from outside is shown on FIG. 1. Essentially, the figure shows a casing 1 surrounding the interface mechanism and provided with a central impression 2 on its upper surface on which the user puts his finger. A cut-out 3 in the centre of the impression 2 exposes the parts of the pins 4 that will be described below and that give the tactile simulation impression.

Refer to FIG. 2, that shows the interface after removal of the casing 1. The pins 4 are arranged to be parallel to each other so as to form a horizontal layer 5. They have a small diameter of about 1 millimetre and have a variable c/c spacing equal to values ranging between 1.5 millimetres (therefore the pins 4 are almost adjacent) and about 3 millimetres. The pins 4 are mounted on corresponding supports 6 that all have a base 7 and a pair of uprights 8. The pins 4 are free to rotate at the ends of the uprights 8 through bearings not shown. The uprights 8 are inclined converging towards the centre of the network such that the bases 7 of the supports 6 can be wider than the pins 4 when the pins are adjacent and therefore stronger. The pins 4 are driven in rotation by motors 9 using oblique transmissions 10 comprising a first universal joint 11 adjacent to the motor 9, a telescopic bar 12, and a second universal joint 13 adjacent to the pin 4, because the diameters of the motors 9 are larger than the diameters of the pins 4. This device is provided for each of the pins 4 in the embodiment shown, so that the pins 4 can be controlled independently. This may be unnecessary, and it would be possible to control all transmissions 10 through a common motor and driving them for example through pulley and belt means leading to the single motor. In this case, the speed ratios for the various pins are constant. The motors 9 and transmissions 10 are distributed on both sides of the layer 5 of pins 4 due to their size. The motors 9 are installed fixed on a frame 14. The bases 7 of the supports 6 are drilled and parallel slides 15 are engaged in the drillings. The slides 15 are installed fixed on the frame 14. Since the bases 7 slide on the slides 15, the supports 6 are installed free to move on the frame 14. Springs 16 inserted on the ends of the slides 15 pull the supports 6 back into a central position. However, one of the supports 6, located in the middle, is retained along the slides 15 by stops or similar means.

FIG. 3 illustrates the bottom of supports 6. The mechanism shown comprises a parallelogram system 17 composed of branches 18 articulated to each other at their ends and articulated at their centre to a corresponding support 6 through a pivot 19. Furthermore, the branches 18 are distributed in two layers with opposite inclinations, and assembled by their articulations to form a single and closed broken line. When two supports 6 are moved away from each, the parallelograms open and all other supports 6 also move away from each other. Therefore, it is possible to adjust the spacing between all pins 4 using a common mechanism. It is a motor 20 shown in FIG. 2 and that rotates a worm screw 21 that moves a nut 22 fixed to one of the supports 6 into which it is engaged.

The pins 4 may consist of rigid threads or small rods. They may have a round section, or preferably they may have edges or striations to simulate some relief or some surface conditions. The pins 4 may have star or polygonal shaped sections. It will be possible to have several sets of different pins 4 and to use the most appropriate set for each service of the interface after removing the old pins.

A thermal module can also be added to the tactile interface to also simulate a temperature difference on the virtual surface. As shown on FIG. 4, it could consist of a plate 27 operating by the Peltier effect that would be placed under the layer 5. The associated radiator 28 can be fixed to the frame 14, that will help with heat dissipation.

Note the advantages of the tactile interface according to the invention, that makes it easy to modify the profile or the section of each of the pins, and their speed and spacing.

1. Tactile interface, characterised in that it comprises a row of rotating pins (4) mounted on corresponding supports and forming a layer (5) on which a user places the fleshy part of a finger, and a support spacing adjustment mechanism (6).

2. Tactile interface set forth in claim 1, characterised in that the pins are parallel.

3. Tactile interface set forth in claim 1, characterised in that the pins are provided with edges.

4. Tactile interface set forth in claim 1, characterised in that the supports slide on guide ways and the spacing adjustment mechanism comprises connections in a parallelogram arrangement between the supports and a means for moving one of the supports.

5. Tactile interface set forth in claim 1, characterised in that it includes a frame (14) on which the pin supports are mounted free to move, at least one pin drive motor (9) mounted fixed onto the frame, and transmissions (10) between the motor and the various pins and comprising first universal joints adjacent to the motor and second universal joints adjacent to the pins, and telescopic transmission bars between the first universal joints and the second universal joints.

6. Tactile interface set forth in claim 1, characterised in that it includes a temperature variation module placed under the layer of pins.

7. Tactile interface set forth in claim 2, characterised in that the pins are provided with edges.

8. Tactile interface set forth in claim 2, characterised in that the supports slide on guide ways and the spacing adjustment mechanism comprises connections in a parallelogram arrangement between the supports and a means for moving one of the supports.

9. Tactile interface set forth in claim 3, characterised in that the supports slide on guide ways and the spacing adjustment mechanism comprises connections in a parallelogram arrangement between the supports and a means for moving one of the supports.

10. Tactile interface set forth in claim 2, characterised in that it includes a frame (14) on which the pin supports are mounted free to move, at least one pin drive motor (9) mounted fixed onto the frame, and transmissions (10) between the motor and the various pins and comprising first universal joints adjacent to the motor and second universal joints adjacent to the pins, and telescopic transmission bars between the first universal joints and the second universal joints.

11. Tactile interface set forth in claim 3, characterised in that it includes a frame (14) on which the pin supports are mounted free to move, at least one pin drive motor (9) mounted fixed onto the frame, and transmissions (10) between the motor and the various pins and comprising first universal joints adjacent to the motor and second universal joints adjacent to the pins, and telescopic transmission bars between the first universal joints and the second universal joints.

12. Tactile interface set forth in claim 4, characterised in that it includes a frame (14) on which the pin supports are mounted free to move, at least one pin drive motor (9) mounted fixed onto the frame, and transmissions (10) between the motor and the various pins and comprising first universal joints adjacent to the motor and second universal joints adjacent to the pins, and telescopic transmission bars between the first universal joints and the second universal joints.

13. Tactile interface set forth in claim 2, characterised in that it includes a temperature variation module placed under the layer of pins.

14. Tactile interface set forth in claim 3, characterised in that it includes a temperature variation module placed under the layer of pins.

15. Tactile interface set forth in claim 4, characterised in that it includes a temperature variation module placed under the layer of pins.

16. Tactile interface set forth in claim 5, characterised in that it includes a temperature variation module placed under the layer of pins.

17. Tactile interface set forth in claim 6, characterised in that it includes a temperature variation module placed under the layer of pins.
